(19) United States
(12) Patent Application Publication
(10) Pub. No.: US 2026/0299050 A1
(43) Pub. Date: Oct. 1, 2026

(54) PROBE, MEASURING DEVICE, AND POWER LINE MONITORING SYSTEM

(71) Applicant: HYDRO-QUÉBEC, Montréal (CA)

(72) Inventors: Dave LACERTE, Saint-Hyacinthe (CA); François BÉLANGER, Saint-Basile-le-Grand (CA); Sylvain RIENDEAU, Varennes (CA); Pierre GINGRAS, Saint-Bruno (CA); Louis DUPONT, Sainte-Julie (CA); Pascal PARADIS, Laval (CA)

(21) Appl. No.: 19/475,840

(22) PCT Filed: May 7, 2024
(86) PCT No.: PCT/CA2024/050617

§ 371 Date: Oct. 16, 2025

(30) Foreign Application Priority Data
May 8, 2023 (CA) 3199072

(51) Int. Cl. G01R 31/58; G01K 1/024; G01K 1/143; G01R 1/04; G01R 19/00; H05K 1/02; H05K 1/189

(52) U.S. Cl. CPC G01R 31/58; G01K 1/024; G01K 1/143; G01R 1/0416; G01R 19/0084; G01R 19/0092; H05K 1/028; H05K 1/189; H05K 2201/10356

(57) ABSTRACT

A probe for a power line phase cable is disclosed. The probe has voltage sensors for sensing electrical voltage of the cable, current sensors for sensing current flowing in the cable, and optionally temperature sensors for sensing a temperature in the vicinity of the cable. The voltage sensor is formed by a flexible printed circuit board intended to extend over a stripped circumferential surface of a concentric neutral of the phase cable, and an electrically conductive shield covering the board. The shield and a printed circuit layer of the board near the shield are connected to a local ground. Radial pressure is applied to press the shield and board against the phase cable. A device for measuring power line operating and environmental parameters and a system for monitoring the power line using one or more probes for phase cables are also disclosed.

### FIELD OF THE INVENTION

The invention generally relates to systems or devices for measuring various parameters relating to power lines, such as in an underground medium-voltage distribution network, and more particularly to a phase cable probe, a measuring device using the probe or several similar probes, and a power line phase cable monitoring system.

### BACKGROUND

Various underground structures and above-ground equipment cabinets can be found in a power distribution network. It is useful to be able to measure various operating and environmental parameters of the power network in such underground structures or equipment cabinets, such as the load current of a possibly three-phase power line, the relative electrical voltage of a power line cable, the temperature of a cable or accessory (such as a joint) on or near the power line, or even the temperature of the surrounding environment (such as soil, etc.).

Existing measuring devices and systems for measuring some of these parameters have a number of shortcomings. For example, voltage measurement requires different methods depending on the equipment present on an insulated cable in an underground distribution structure, such as a joint or other accessory. Voltage can be read using a capacitive tap, which is generally only available on certain accessory models. Voltage can also be read at the low-voltage stage of a transformer, which is only present in locations equipped with MV/LV (medium-voltage/low-voltage) transformers. Voltage can also be read by a resistive or capacitive divider connected directly to the live conductor, which is only available on multiple-output joints with accessible locations. Otherwise, no voltage reading is typically possible for a given conductor. With current techniques, voltage measurement points must have been planned when the electrical network was built. Adding new voltage measurement points requires de-energizing the line.

The number of three-phase lines in underground structures and electrical distribution cabinets varies. Existing systems for power line metering are designed on the premise that a system can support a fixed number of lines, as the connectors for the metering devices are integrated into the system (usually a single box), which also includes a communication gateway. If the application requires fewer lines than the system's capacity, part of the system is unused. If the application requires more lines than the system can handle, several systems have to be installed, each containing unnecessary redundant parts. In both cases, this entails additional hardware costs, additional physical space and wires, higher system power requirements, and a higher probability of failure and therefore additional maintenance. Moreover, if several systems are to be installed, several communication gateways are required, which are not necessarily designed to be installed in parallel in the same structure or cabinet. Also, existing systems are not adapted to operate properly in the presence of moisture, sediment, oil, gasoline, solvents and other chemical contaminants that may be present in the environment, which may be subject to flooding.

Power supply systems with current transformers (“Energy Harvesting” of a conductor's magnetic field) are designed with a transformer whose secondary side is connected by a detachable cable to a power control system. If the transformer is installed on a cable carrying a high current and the transformer secondary side is open (connector not connected to a load), this may induce a high voltage at the current transformer secondary side. There is a risk of damage to the transformer, and a health and safety risk of electrocution for the person handling the transformer/wire/connector.

Existing underground line fault detectors generally have fixed fault detection thresholds. Some detectors are configurable, but only at the factory and cannot be changed later. Many detectors only signal faults locally, e.g. in the form of a mechanical indicator (“flag”), light or sound. When a fault occurs, a team has to visit each of the structures or cabinets where the line runs to verify on site which detectors are indicating an alarm, and thus locate the likely location of the problem that caused the fault.

There is therefore a need for a power line measuring device that can be versatile, modular, electronically configurable, self-powered by the power line, robust, safe, that can measure an electrical voltage from a cable with or without a semiconductor on the surface, and that can signal the detection of a fault and transmit various data to a remote server in communication with the power line measuring device.

### SUMMARY

According to an embodiment of the invention, there is provided a probe for a power line phase cable, the probe comprising:
a voltage sensor having:
   a flexible printed circuit board having first and second printed circuit layers sandwiched between electrically insulating layers, the flexible printed circuit board being configured for extending over a stripped circumferential surface of a concentric neutral of the phase cable, with the first printed circuit layer being closer to the phase cable than the second printed circuit layer; and
   an electrically conductive shield having interconnected flexible shield elements extending over respective lateral sides of the flexible printed circuit board, and connection to a local ground and to the second printed circuit layer to define an equipotential reference of the shield and the second printed circuit layer, the flexible shield elements defining contact surfaces with the circumferential surface of the phase cable;
a clamping assembly having a surface for applying pressure to the flexible shield elements and the flexible printed circuit board in a radial direction of the phase cable to press the flexible shield elements and the flexible printed circuit board against the circumferential surface of the phase cable;
a current sensor having a sensing element for sensing current flowing in the phase cable to produce a signal indicative of the current, and
a housing containing circuitry connected to the voltage and current sensors, the voltage and current sensors being attached to the housing, and the circuitry having outputs for transmitting a signal indicative of a voltage between the first and second printed circuit layers and the signal indicative of the current. In some embodiments, the clamping assembly can be integrated with the conductive shield.

According to another embodiment of the invention, a device is provided for measuring operating and environmental parameters of a power line, the measuring device comprising:
for each phase cable of the power line, a probe installable around the phase cable, the probe having a voltage sensor for sensing the electrical voltage of a conductor of the phase cable, a current sensor for sensing the current flowing in the conductor of the phase cable, a temperature sensor in the vicinity of the phase cable, and circuitry for transmitting signals indicative of the voltage, current and temperature measured by the sensors; and
an acquisition unit having:
   a power supply circuit connectable to a power source, the circuitry of each probe being powered by the power supply circuit;
   an acquisition circuit powered by the power supply circuit, the acquisition circuit having inputs for receiving analog signals and digital signals including the signals transmitted by the circuitry of each probe, an analog-to-digital converter for converting the analog signals into digital signals, and an output for transmitting data representing the digital signals; and
   a controller powered by the supply circuit and connected to the acquisition circuit, the controller having a programmable mode of operation defining data processing including data transmitted by the acquisition circuit and a controller response, and a communication interface for transmitting the data processed by the controller and receiving data for programming the mode of operation of the controller.

According to another embodiment of the invention, there is also proposed a system for monitoring phase cables of a power line, the monitoring system comprising:
for each phase cable of the power line, a probe installable around the phase cable, the probe having a voltage sensor for sensing the electrical voltage of a conductor of the phase cable, a current sensor for sensing the current flowing in the conductor of the phase cable, a temperature sensor in the vicinity of the phase cable, and circuitry for transmitting signals indicative of the voltage, current and temperature measured by the sensors;
an acquisition unit connectable to a power supply, the acquisition unit having inputs for receiving analog signals and digital signals including signals transmitted by the circuitry of each sensor, circuitry for processing signals received at the inputs including circuitry having a programmable mode of operation defining processing of signals received at the inputs and a response from the acquisition unit, and a communication interface for transmitting data processed by the acquisition unit and receiving data for programming the mode of operation of the circuitry having a programmable mode of operation; and
a communication gateway connected to the communication interface of the acquisition unit, the communication gateway having circuitry for transmitting the data to a remote server via a telecommunications network and receiving the programming data from the remote server via the telecommunications network.

According to an embodiment of the invention, there is provided a probe for a power line phase cable, the probe comprising:
an electrical voltage sensor having:
   a flexible printed circuit board configured to extend over a stripped circumferential surface of a concentric neutral of the phase cable and including a capacitive divider for measuring a conductor voltage; and
   an electrically conductive shield extending over respective lateral sides of the flexible printed circuit board defining first contact surfaces with the circumferential surface of the phase cable, the shield including a connection to a local ground and to the capacitive divider to define an equipotential reference of the shield and the capacitive divider;
a clamping assembly configured to press the shield and the flexible printed circuit board against the circumferential surface of the phase cable; and
a housing containing circuitry connected to the voltage sensor, the circuitry having an output for transmitting a signal indicative of the voltage measured by the voltage sensor.

The following provides an overview of some possibly preferable features of the invention which are to be considered non-limiting and will be described in more detail below.

Each power line can be equipped with an independent measuring device communicating over a local network. Each measuring device can include one or more probes, depending on whether the line is single-phase, two-phase or three-phase, and on the requirements of the phase cables to be monitored. A single gateway can link a network of several local wired or wireless measuring devices (e.g. IEEE 802.15.4 or 10BaseT1S protocol) to a telecommunications network, e.g. cellular. The power supply for a measuring device can advantageously come from a current transformer that is integral with the measuring device and cannot be disconnected from it, so that the secondary of the current transformer will never be open-circuited. The current transformer can advantageously be of the type that generates power from a cable's magnetic field. The measuring device can report a fault and other data as required to a remote server via the gateway, and can receive configuration data including fault detection thresholds or curves. Each measuring device can be remotely reprogrammed, which also enables a fault detection algorithm to be added or modified after deployment. Measuring devices can be installed in various underground structures and cabinets of above-ground equipment in a power distribution network. For three cables on the same three-phase line, a measuring device can continuously measure load current (RMS value), relative voltage (RMS value), capture current and voltage waveforms in real time (with time stamping), continuously measure cable temperature (near a joint or accessory), continuous reading of signals from external measuring instruments, such as a temperature probe in a duct bank, continuous measurement of ambient temperature in the structure, real-time detection of electrical faults, e.g. according to IEEE C37.2, such as overcurrent (function 50/50TD), di/dt (function 7C), loss of charge (function 37), loss of voltage (function 27), fault directionality (voltage/current phasors, function 67), with configurable function levels and logic.

The measuring device according to the invention can be installed on an insulated cable and allows measuring current, voltage and, optionally, temperature. In an embodiment, the measuring device, with its probe(s), can be installed while energized and under load on an insulated cable that can be coated with a semiconducting layer and a concentric neutral as used, for example, on Hydro-Québec's medium-voltage underground network. In normal operation and during a fault, current can flow over the concentric neutral. This can affect the measurement of load and current flowing in the cable conductor during a fault, but has no impact on the inductive power. A probe can be installed on a cable covered with insulation and stripped of its concentric neutral if present (typically on either side of a cable joint), while the current transformer for the power supply can be installed on a section of cable covered with a concentric neutral. The measuring device with its probe(s) is not intended for direct installation on an uninsulated conductor, such as an overhead distribution network conductor.

The invention is suitable for use in the difficult operating environment of an underground network. The components and materials of the measuring device in contact with the cable can be chosen to withstand the maximum temperatures of the intended application (typically from 125° C. to 150° C.). The watertight housing can be filled with a sealant to guarantee watertightness. Exposed parts of the measuring device, such as the housing, the cable between the probes and the acquisition unit, and the flexible section of the circuitry, can be selected for operation in the presence of moisture, sediment, oil, gasoline, solvents and other chemical contaminants that may be present in the environment. The measuring device assembly can be used when submerged in liquid (typically up to 5 m). Its mechanical and electrical design can eliminate worker safety risks, facilitate installation, and simplify commissioning and maintenance.

### BRIEF DESCRIPTION OF DRAWINGS

A detailed description of preferred embodiments of the invention will be provided below with reference to the following drawings:

FIG. 1 is a block diagram illustrating a power line phase cable monitoring system according to an embodiment of the invention.

FIG. 2 is a block diagram illustrating a power supply circuit for a power line measuring device according to an embodiment of the invention.

FIG. 3A is a cross-sectional view of a probe for a power line phase cable comprising a capacitive voltage sensor, according to an embodiment of the invention.

FIG. 3B is a cross-sectional view of a probe for a power line phase cable comprising a capacitive voltage sensor, according to another embodiment of the invention in which the voltage sensor comprises a clamping assembly integrated right into a conductive shield.

FIG. 4A is a cross-sectional view of the capacitive voltage sensor of the probe of FIG. 3A, according to an embodiment of the invention.

FIG. 4B is a cross-sectional view of the capacitive voltage sensor of the probe of FIG. 3B, according to another embodiment of the invention.

FIG. 5 is a schematic perspective diagram illustrating a monitoring system according to an embodiment of the invention.

FIG. 6 is a perspective schematic diagram illustrating a power line measuring device installed near a joint according to an embodiment of the invention.

FIG. 7 is a schematic diagram illustrating an equivalent circuit of a power line phase cable for relative voltage acquisition according to an embodiment of the invention.

FIG. 8 is a schematic diagram illustrating a simplified modeling of the flexible printed circuit board for capacitive coupling of the probe of FIG. 3A, according to an embodiment of the invention.

FIG. 9 is a schematic diagram illustrating a simplified modeling of a coupling of a flexible printed circuit board with a medium-voltage electrical cable according to an embodiment of the invention.

### DETAILED DESCRIPTION OF PREFERRED EMBODIMENTS

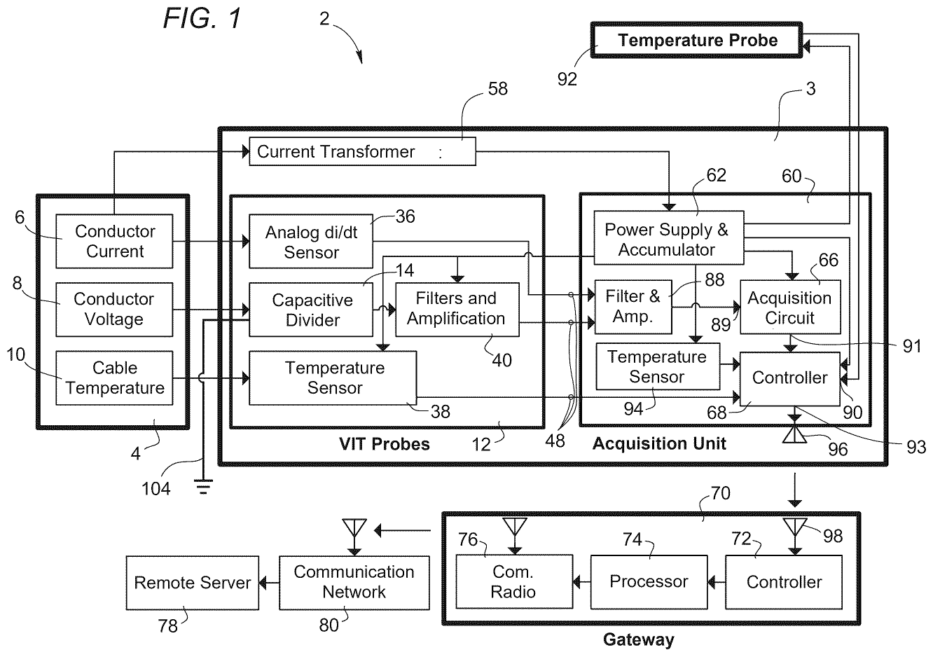

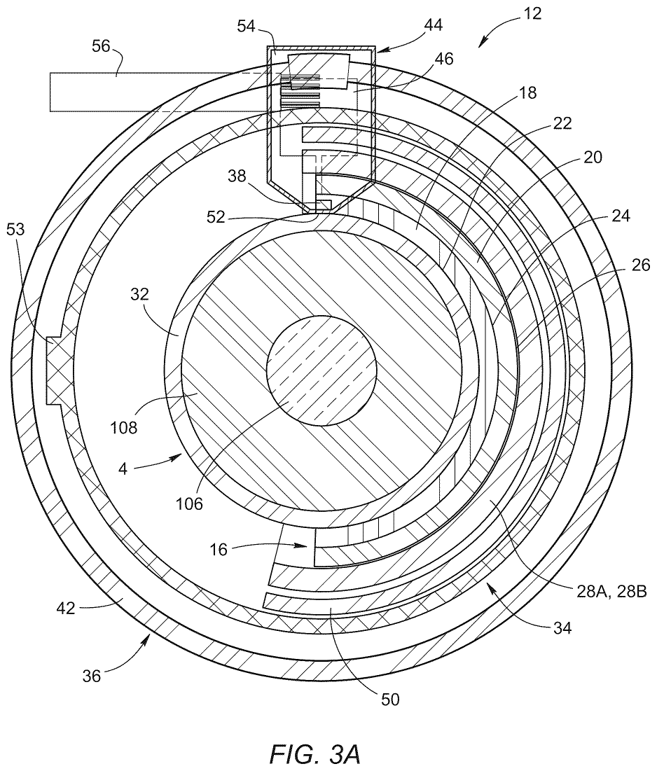

With reference to FIG. 1, a system 2 for monitoring phase cables 4 of a three-phase power line according to an embodiment of the invention is shown. It should be noted that the system 2 can also be used for a single-phase power line (having a single phase cable) or two-phase power line (having two phase cables), and for several power lines rather than one. System 2 is designed to monitor, for each phase cable 4 of the power line, the current flowing in conductor 106 (illustrated e.g. in FIGS. 3A and 3B) of phase cable 4 as illustrated by block 6, the electrical voltage of conductor 106 as illustrated by block 8, and optionally though advantageously the temperature of phase cable 4 as illustrated by block 10. To this end, the system comprises a number of probes 12 corresponding to the number of phase cables 4 of the power line. Each probe 12 comprises a voltage sensor 14 in the form of a capacitive divider for measuring a voltage of the conductor 106 of the phase 4 cable, a current sensor 36 for measuring a current flowing in the conductor 106 of the phase 4 cable, a temperature sensor 38 (optional) for measuring a temperature in the vicinity of the phase 4 cable, and a voltage conditioning circuit 40. For the purposes of the following description, probes 12 may be referred to as “VIT probes” (V for voltage, I for current and T for temperature). The VIT 12 probes are connected to an acquisition unit 60. The acquisition unit 60 and the VIT 12 probes form a device for measuring 3 power line operating parameters and environmental parameters according to the invention.

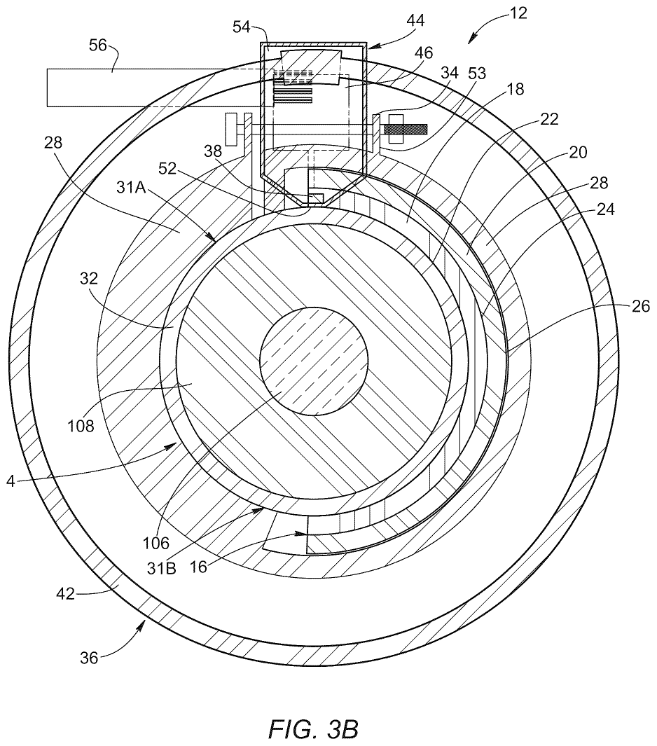

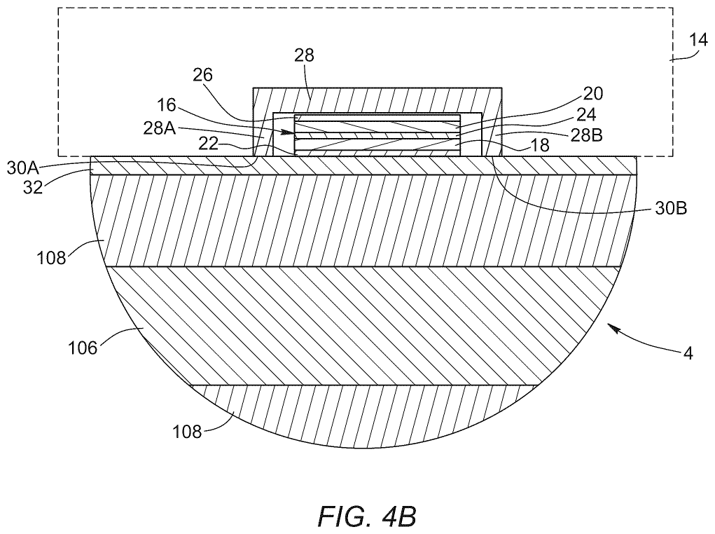

Referring to FIG. 3A and FIG. 4A, according to an embodiment, the voltage sensor 14 comprises a flexible printed circuit board 16 having first and second printed circuit layers 18, 20 sandwiched between electrically insulating layers 22, 24, 26. The flexible printed circuit board 16 is configured for extending over a stripped circumferential surface 110 (illustrated in FIG. 6) of the concentric neutral of the phase cable 4, with the first printed circuit layer 18 being closer to the phase cable 4 than the second printed circuit layer 20. The flexible printed circuit board 16 can have a length close to the maximum of the circumference of the smallest intended underground electrical distribution phase cable 4 to maximize the voltage collection area and enable its use on larger phase cables. The first layer 18 is intended to serve as a floating sensing electrode, while the second layer 20 is intended to serve as a reference measurement point connected to a local ground 104 (illustrated e.g. in FIG. 6) of the measuring device 3. The voltage sensor 14 also comprises an electrically conductive shield 28 having interconnected flexible shield elements 28A, 28B extending on respective lateral sides of the flexible printed circuit board 16, and a connection to the local ground 104 and to the second printed circuit layer 20 to define an equipotential reference of the shield 28A, 28B and the second printed circuit layer 20. Shield elements 28A, 28B define first contact surfaces 30A, 30B (shown in FIG. 4A) with the circumferential surface of phase cable 4, which are intended to extend in a circumferential direction of phase cable 4. In an embodiment, the flexible shield elements 28A, 28B are formed by a wire (or wires) having a diameter similar to a thickness of the flexible printed circuit board 16, and segments extending along the lateral sides of the flexible printed circuit board 16. The shield can advantageously comprise shield elements (not illustrated) extending over ends of the flexible printed circuit board 16 (so as to surround the flexible printed circuit board 16 on all sides) and defining second contact surfaces with the circumferential surface of the phase cable 4, all shield elements 28A, 28B (and those at the ends of the flexible printed circuit board 16 being interconnected without forming a closed loop around the flexible printed circuit board 16. In this way, the shield can be formed by a single wire surrounding the flexible printed circuit board 16, with the wire ends not being connected to one another.

Other embodiments of the shield are possible. For example, with reference to FIG. 3B and FIG. 4B, according to an embodiment, the voltage sensor 14 comprises an electrically conductive plate covering the flexible printed circuit board 16 and defining the shield 28, the plate having a curvature and degree of flexibility compatible with the circumferential surface of the phase cable, and flanges projecting to the sides of the flexible printed circuit board 16 to form the shield elements 28A, 28B defining first contact surfaces 30A, 30B with the circumferential surface of the phase cable 4. The shield includes an integral clamping assembly 34 (described below) comprising a clamp 53 defining second contact surfaces 31A, 31B at the ends of the flexible printed circuit board 16. The first and second contact surfaces 30A, 30B, 31A and 31B are configured to bear against an outer semiconductor 32 (around insulator 108) of phase cable 4 so as to surround flexible printed circuit board 16 on all sides, and to form an equipotential reference on semiconductor 32. The grounding of semiconductor 32 by shield 28 is thus achieved by a connection independent of the measurement. Shield 28 reduces the variability of the voltage signal depending on the installation environment, e.g. the integrity of the concentric neutral 110 (shown in FIG. 6) of phase cable 4 in the case of a MV cable, the possible submersion of phase cable 4, the length of phase cable 4, etc., by forcing a low impedance around the flexible printed circuit board 16 acting as a voltage sensing element.

Referring to FIG. 3A, a clamping assembly 34 extendable around the shield 28A, 28B has a pressure-applying surface on the shield elements 28A, 28B and the flexible printed circuit board 16 in a radial axis of the phase cable 4 (e.g. directed towards the central axis of the phase cable 4) to press the shield elements 28A, 28B and the flexible printed circuit board 16 against the circumferential surface of the phase cable 4. The flexible printed circuit board 16 is thus directly applied to the outer surface of the phase cable 4, and in particular to the semiconductor 32. The exposure of the flexible printed circuit board 16 to magnetic field lines can be minimized by the absence of contact between layers 18, 20 and a reduced thickness of the flexible printed circuit board 16 around the phase cable 4 so as to minimize the surface area exposed to field lines.

Other embodiments of clamping assembly 34 are possible. For example, in the embodiment shown in FIG. 3B, the clamping assembly 34 is integrated with the shield 28, which may offer an advantage in terms of the quality of contact of the equipotential reference applied to the semiconductor 32. In this embodiment, shield 28 is configured as a clamp 53 that extends around phase cable 4. The clamp 53 is adjustable to apply pressure to the flexible printed circuit 16 in the radial direction towards the phase cable 4.

The current sensor 36 has a sensing element 42 for sensing current flowing in the phase cable and producing a signal indicative of the current. Advantageously, the sensor element 42 can comprise a Rogowski winding assembly which can be installed around the phase cable 4 to produce the current-indicating signal. In this case, the current sensor 36 produces a signal representing the derivative of the current flowing through it. This type of sensor enables AC currents to be read over a wide range (e.g. from 1 ampere to over 60,000 amperes) without suffering from saturation or minimum reading current (magnetization). Current sensor 36 can be flexibly installed on phase cable 4 without interrupting the load flowing through conductor 106.

A housing 44 contains circuitry 46 which may be formed, for example, by a printed circuit board. Circuitry 46 is connected to voltage sensor 16 and current sensor 36. The voltage sensor 16 and the current sensor 36 are attached to the housing 44. The circuitry 46 has outputs 48 (shown in FIG. 1) for transmitting a signal indicative of a voltage between the first and second printed circuit layers 18, 20, and for transmitting the signal indicative of the current measured by the current sensor 36. Conditioning circuitry 40 (shown in FIG. 1) can be integrated with circuitry 46 and connected to the flexible printed circuit board 16 to produce the signal indicative of the voltage. The conditioning circuitry 40 may contain signal amplification and filtering electronics, such as a low-pass filter or integrator circuit. The circuitry 46 can be oriented in the axis of the field lines of conductor 106 of phase cable 4 to minimize inductive disturbances on the electronics. The arrangement of the housing 44 and the voltage sensor 14 also enables the current sensor 36 to be positioned perpendicular to the phase cable 4 and centered on the phase cable 4, improving the accuracy and reliability of current measurement. In an advantageous embodiment, the housing 44 defines a watertight chamber 54, and a watertight cross-over multipair cable 56 connected to circuitry 46 and exiting the housing 44 can be used to transmit signals from the VIT 12 probe to the acquisition unit 60 (shown e.g. in FIG. 1), and supply power to the electronics in the probe 12. Thus, one pair of the multipair cable 56 can be used to supply power to the conditioning circuitry 40 (shown in FIG. 1), another pair to transmit the conditioned analog signal from the voltage sensor 16, another pair to transmit the analog signal from the current sensor 36, and another pair to transmit the signal from the temperature sensor 38. The multipair cable 56 can advantageously have a shield connected at one end to the shield 28A, 28B of the voltage sensor 16 and at the other end to the local ground 104 of the measuring device 3 (shown e.g. in FIG. 1). The multipair cable 56 may have a protective sheath for mechanical protection and watertightness. A cable gland (not shown) can be used to connect the multipair cable 56 to the acquisition unit 60. The housing 44 can be filled with a sealant (not shown) to guarantee its watertightness.

In an embodiment, the voltage sensor 16 and the current sensor 36 have the same concentric axis corresponding to the central axis of the phase cable 4, and the current sensor 36 extends on an outer side of the voltage sensor 16 with respect to the phase cable 4 (opposite to an inner side of the voltage sensor 16 adjacent to the phase cable 4).

According to the embodiment shown in FIG. 3A, the clamping assembly 34 is formed by a non-conductive mechanical tongue 50 projecting from the housing 44 and extending over an outer periphery of the shield 28A, 28B, and an adjustable clamp 53 attached to the housing 44 and extending over an outer periphery of the tongue 50 to exert a force on the tongue 50 and thus on the shield 28A, 28B so as to optimize contact between the outer surface of the phase cable 4 and the flexible printed circuit board 16. The adjustable clamp 53 can pass through the housing 44 via a passage provided for this purpose.

Other configurations of clamping assembly 34 are possible. For example, according to the embodiment shown in FIG. 3B, clamping assembly 34 is formed by an adjustable clamp 53 integral with shield 28, for exerting a force to optimize contact between the outer surface of phase cable 4 and flexible printed circuit board 16, and between the outer surface of phase cable 4 and shield 28 on contact surfaces 30A, 30B, 31A, and 31B. The clamp 53 can pass through the housing 44 via a passage provided for this purpose.

According to an embodiment, the housing 44 a has a bottom face 52 that is complementary with the circumferential surface of the phase cable 4 for positioning the housing 44 on or near the phase cable 4, and the flexible printed circuit board 16 projects out of the housing 44 adjacent to the bottom face 52 of the housing 44 in a direction of the circumferential surface of the phase cable 4.

The configuration of a VIT 12 probe as described above is particularly suited to a MV cable 4 formed by a central conductor 106 (e.g. copper or aluminum) covered by an electrical insulator 108 (e.g. tree retardant cross-linked polyethylene), which is generally covered by a semiconductor 32 (or semiconductor sheath which is intended to even out the electric field at the surface of the cable 4. The material of semiconductor 32 may be a black compound containing carbon. The semiconductor 32 is in turn covered by a braided strip or arrangement of conductors (e.g. in corrosion-resistant copper or aluminum) forming the concentric neutral 110 (illustrated in FIG. 6). The concentric neutral 110 captures charges accumulating on the surface of the semiconductor 32 and, via the concentric neutral 110, returns them to local ground at various points on the electrical network. In the concentric neutral 110, a leakage current flows from the charges in the concentric neutral 110 proportional to the length of the cable 4, as well as a current caused by the unbalanced load of the electrical network. To measure only the current of the central conductor 106, the current sensor 36 is installed at a location where the concentric neutral 110 is absent, as shown in FIG. 6. The same location can advantageously be used to measure voltage by applying the sensing electrode 18 to the surface of the cable 4, so as to act as a capacitive divider. A longitudinal conduction current in the axis of cable 4 flows in the portion of semiconductor 32 devoid of concentric neutral 110. As the semiconductor 32 is much more resistive than the concentric neutral 110, a linear voltage (surface potential differences or longitudinal gradient) develops on and in the semiconductor up to the point of contact with the concentric neutral 110. Contact with the concentric neutral 110 is imperfect and variable depending on the state of wear of the concentric neutral 110 and the environment (humidity, liquids, pollutants, etc.). The sensing electrode 18 of the voltage sensor 14 is affected by the contact between semiconductor 32 and concentric neutral 110, as well as by the distance separating it from concentric neutral 110. On a 14.4 kV MV cable, the voltages observed at the surface of the semi conductor 32 away from the concentric neutral 110 vary from one installation to another and over time by several volts. Variations of a factor of 100 or more can also be observed, depending on the condition of cables 4 and their environment. These large variations in the conduction current to the concentric neutral 110 can directly affect the amplitude of the voltage at the sensing electrode 18 of the capacitively coupled voltage sensor 14. Due to the lateral contact surfaces 30 of the shield 28A, 28B of the VIT 12 probe pressed against the semiconductor 32 by the clamping assembly 34 to enable better electrical contact between the semiconductor 32 and the shield 28A, 28B, the conduction current on and in the semiconductor 32 is directed on either side of the voltage sensor 14 towards the local ground 104 (shown in FIG. 6). As a result, the space between the lateral contact surfaces 30 where the sensing electrode 18 is located forms an island where only the displacement current from the insulator 108 beneath this island flows, eliminating installation environment variabilities.

In an embodiment, the temperature sensor 38 is contained in the housing 44 close to or in contact with the underside 52 of the housing 44, and is connected to the circuitry 46 to transmit the signal indicative of the temperature to one of the outputs 48 of the circuitry 46. The temperature sensor 38 can advantageously be a digital temperature sensor so that the temperature signal it produces is not susceptible to electromagnetic fields from the environment and does not have to be converted for processing by a processor or controller. The temperature sensor 38 can thus be used to read the temperature of the phase cable 4 or of an accessory such as a joint 112 (illustrated in FIG. 6) in the vicinity of the temperature sensor 38. The temperature sensor 38 can use low-speed “1-Wire” communication. The temperature sensor 38 can be mounted on circuitry 46.

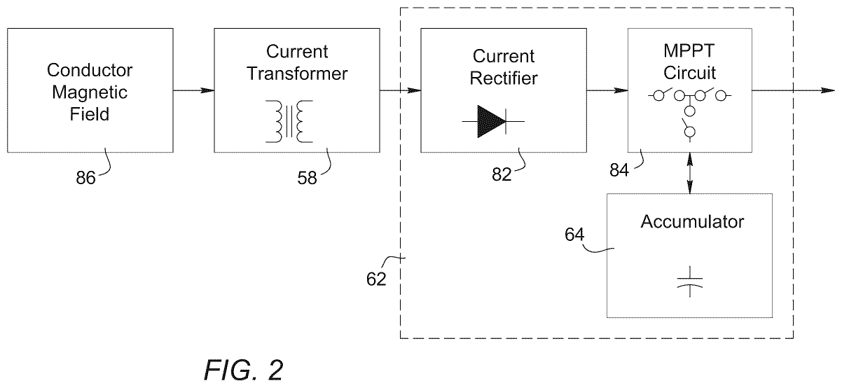

Referring again to FIG. 1, the acquisition unit 60 has a power supply circuit 62 connectable to a power source, for example an external AC or DC source (not shown) if available, to power the various components of the measuring device 3 such as the circuitry 46 (shown in FIGS. 3A and 3B) of each VIT sensor 12, and other possible devices or equipment associated with the measuring device 3. According to an embodiment, the power source can advantageously be implemented by a current transformer 58 coupling to one of the phase cables 4 to capture a magnetic field 86 (illustrated in FIG. 2) generated by the phase cable 4 and generate electrical energy supplied to the power supply circuit 62 (a technique known as “Energy Harvesting”). Supply circuit 62 is then connected to current transformer 58.

In an embodiment, the current transformer 58 a has an openable “split core” air gap, enabling the measuring device 3 to be used at locations such as on cables that are already in place and operational in an underground electrical distribution network where no low-voltage power source is directly available. The current transformer 58 can thus comprise two parts, the first being movable and containing part of the magnetic core, the second comprising the second part of the magnetic core and a winding. The part of the current transformer 58 with the winding is integral with the acquisition unit 60 of the measuring device 3. The winding of the current transformer 58 is thus permanently connected to the power supply circuit 62. This configuration enables the measuring device 3 to be installed on a phase cable 4 without interrupting the power supply to the power line. This configuration also prevents the current transformer 58 from being used at no load, and thus protects it from overvoltage at its secondary in this inapplicable case of use. Preferably, the two air-gap portions of current transformer 58 are provided with a sealing protection, such as a rubber gasket (not shown).

Referring to FIG. 2, in an embodiment with the current transformer 58 as the power source, the power supply circuit 62 includes a current rectifier 82 at the input, connected to the current transformer 58, to convert the electrical energy received from the current transformer 58 in the form of an alternating current into a regulated low voltage direct current. The power supply circuit 62 also includes an accumulator 64 for storing and releasing electrical energy, and an output Maximum Power Point Tracking (MPPT) controller 84, connected to the current rectifier 82 and the accumulator 64, for recharging the accumulator 64 with excess energy and drawing electrical energy from the accumulator 64 to maintain a minimum output power level. This type of power supply circuit 62 first prioritizes powering the electronic components of the measuring device 3 (including the VIT 12 probes) before recharging the accumulator 64 with the excess energy that can be supplied by the current transformer 58 whenever possible. In addition, the MPPT circuit 84 can use the energy stored in the accumulator 64 when the current coming from the rectifier 82 is no longer sufficient to supply the measuring device 3. The accumulator 64 can advantageously be of the hybrid supercapacitor type, for example lithium, offering a better energy density than an ordinary supercapacitor, a wider operating temperature range, and having a longer life than a lithium battery.

Referring again tola FIG. 1, an acquisition circuit 66 powered by the power supply circuit 62 has inputs 89 for receiving analog signals and digital signals including signals transmitted by the circuitry 46 (shown in FIGS. 3A and 3B) of each VIT 12 probe. The acquisition circuit 66 has an analog-to-digital converter (not shown) for converting the analog signals into digital signals, and an output 91 for transmitting data representing the digital signals. A controller 68 powered by the supply circuit 62 is connected to the acquisition circuit 66. The controller 68 has a programmable operating mode defining a data processing that includes the data transmitted by the acquisition circuit 66 as well as a response of the controller 68 to a received command. A communication interface 93 is used to transmit the data processed by the controller 68 and to receive programming data for the operating mode of the controller 68.

In the case where a VIT 12 probe includes a digital temperature sensor 38, it is powered by the supply circuit 62 of the acquisition unit 60 and the signal indicative of the temperature produced by the temperature sensor 38 can be transmitted directly to the controller 68 rather than passing through the acquisition circuit 66.

In an embodiment, the acquisition unit 60 can advantageously comprise input anti-replication filters and a circuit for conditioning 88 analog signals prior to digitization by the analog-to-digital converter of the acquisition circuit 66. The analog-to-digital converter used may be a specialized converter designed for measuring energy and the quality of the electrical wave, and in particular may be a converter for three-phase AC circuits.

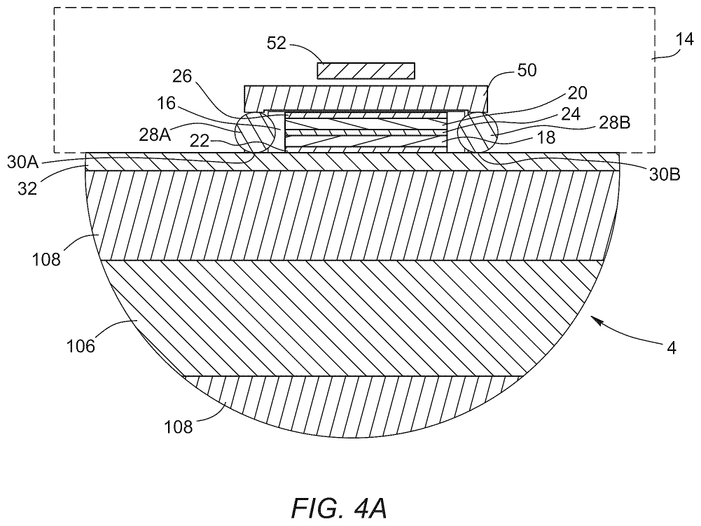

Also, the acquisition unit 60 may be provided with an internal temperature sensor 94 to produce a signal indicative of a temperature in the environment of the acquisition unit 60, for example in the acquisition unit 60 or the immediate environment of the measuring device 3. If the temperature sensor 94 is of the digital type, then it can be powered by the power supply circuit 62 and connected directly to the controller 68. Due to the low power consumption and compact size of the measuring device 3, positioning the temperature sensor 94 close to the surface of the housing 102 (illustrated e.g. in FIG. 5) of the acquisition unit 60, opposite the current transformer 58, enables a temperature deviation from the ambient temperature in a structure or cabinet to be characterized, which can be useful for estimating the temperature of the insulation 108 near the conductor 106 of a cable 4 (illustrated e.g. in FIGS. 3A and 3B) of a power line in an underground duct bank (not illustrated), or the heating of a cable joint 112 (illustrated in FIG. 6).

The controller 68 may have an interface 90 connectable to measuring instruments external to the measuring device 3, such as an external temperature sensor 92 (or several). If required, the measuring instrument can be powered by the power supply circuit 62.

In an embodiment, the monitoring system 2 comprises a communication gateway 70 connected to the controller 68 of the acquisition unit 60. The communication gateway 70 has a circuit which can be formed by a controller 72, a processor 74 and a radio circuit 76 such as a cellular modem, for transmitting data to a remote server 78 via a telecommunication network 80 and receiving from the remote server 78 via the telecommunication network 80 the programming data communicated to the controller 68 of the acquisition unit 60.

According to a possible mode of operation, the controller 68 processes the signals from the acquisition circuit 66, the temperature sensors 38 of the VIT 12 probes, instruments such as the external temperature sensor 92 and the internal temperature sensor 94, and retransmits them wirelessly over a local area network (e.g. according to the IEEE 802.15.4 standard) as illustrated in FIG. 5. In an embodiment, the controller 68 incorporates a radio circuit (not shown) compatible with the IEEE 802.15.4 standard in the 2.4 GHz band. Another type of controller with or without integrated radio can be used if desired. The radio circuit can use other bands, e.g. 900 MHz ISM (Industrial, Scientific and Medical), or other wireless communication technologies such as cellular. An optional “daisy-chain” wired communication port (not shown) can also serve as a communication link and, if required, a power supply between the measuring devices 3 and the gateway 70, for example an SPE (“Single Pair Ethernet”) link or according to the IEEE 10BASE-T1S standard.

Referring to FIG. 5, according to an embodiment, the acquisition unit 60 and the gateway 70 can have a connection via antennas 96, 98. The antenna 96 is connected to the controller 68 (illustrated in FIG. 1) and enables communication with the gateway 70. The antenna 96 can be internal to the housing 102 of the acquisition unit 60 for use in unflooded environments. Alternatively, the antenna (referred to as 96′) can be located outside the housing 102 by means of a 100 cable to be positioned in a non-floodable location, for example on the ceiling of a structure, or in a 108 watertight housing where all the antennas of the measuring devices 3 of the structure and the 98 antenna of the 70 gateway are located. In another possible embodiment, the cable 100 could be connected directly to the gateway 70. In a further embodiment, the antenna 96 is passively coupled to a (non-illustrated) antenna external to the housing 102, and the external antenna is connected to the cable 100.

Referring to FIG. 6, according to an embodiment, the ground 104 of the measuring device 3 is connected to the outer concentric neutral 110 of one of the phase cables 4 of the power line, for example where the concentric neutral 110 is coupled to a bypass connection 111 of the joint 112. Such a ground serves to read the voltage by capacitive coupling built into the VIT 12 probe. It also serves to protect the analog signals of the VIT 12 probes from electric field interference.

Referring again to FIG. 1, an example of data and data paths in the monitoring system 2 is described in relation to an underground three-phase medium-voltage (MV) electrical distribution line. It should be understood that the invention is not limited to this particular environment. Each measuring device 3 can acquire the following time-referenced values for real-time measurement and operation of the power network:
for each VIT 12 probe, generally corresponding to the phases (A, B, C):
the root mean square (RMS) value (fundamental at the power line frequency and/or True RMS) of the current carried by MV conductor 106 (illustrated e.g. in FIGS. 3A and 3B);
the RMS value (fundamental at the power line frequency and/or True RMS) of the voltage carried by MV conductor 106 and transferred to semiconductor 32 (shown e.g. in FIGS. 3A and 3B) of MV cable 4;
the surface temperature of the semiconductor 32 of the MV cable 4 under the VIT 12 probe, and possibly an abnormal temperature rise of a nearby distribution network accessory, e.g. joint 112 (illustrated in FIG. 6).
for the structure (not shown) where the measuring device 3 is installed:
ambient temperature;
the temperature of an external sensor 92 which can be used, for example, to read the temperature of a duct bank (not illustrated), other temperatures on joint 112, etc.

These values can be transmitted according to the requirements of the application at fixed intervals (for example, from one second to one day), using the deadband principle (data refreshed only when there is a predefined variation from the last data sent) or on demand.

In addition, each measuring device 3 can simultaneously acquire the following curves (or waveforms):
for each VIT 12 probe:
the curve of the instantaneous current carried by conductor 106 as digitized by the analog-to-digital converter of acquisition circuit 66;
the curve of the voltage coming from the capacitive divider 14 of the VIT 12 probe fixed to the surface of the cable 4, as digitized by the analog-to-digital converter of the acquisition circuit 66.

A sufficiently high sampling rate of the curves enables analysis by fault-locating algorithms. For example, the sampling rate can be at least 64 points per 60 Hz network cycle, and each curve can contain a configurable number of cycles, such as 10. These curves can be transmitted to the remote server 78 for processing, as required according to the application:
at fixed intervals;
capture on demand;
upon detection of an event configured in the measuring device 3, such as detection of a fault according to a threshold or curve, etc.

Time synchronization of the data acquisition and the waveforms for time referencing of values can be achieved by the wireless or wired communication link with a GPS receiver (not shown) in the gateway 70, synchronization frames of the communication network 80 if cellular, or by a remote time server (not shown) which can, for example, be implemented in the remote server 78. Time synchronization of this kind makes it possible to pinpoint the precise location of a fault, to correct the phasing of current and voltage measurements, and can be used for power grid control by PMU (“Phasor Measurement Unit”).

Data can be sent from measuring device 3 to gateway 70 over the wireless network implemented by controller 68 (e.g. according to the IEEE 802.15.4 standard), antennas 96, 98, and controller 72 (e.g. according to the IEEE 802.15.4 standard). The data can then be transmitted from the gateway 70 to the remote server 78 via the long-range network 80 (e.g. cellular). The data can then be stored at the remote server 78. Analysis and processing of the curves and of the measured values (current, voltage and temperature) can be carried out at the remote server 78, for example, to locate faults according to the phase of the voltage and current during the event. Some processing and calculations, such as harmonic calculations and power quality analysis, can also be performed by the controller 68 of the measuring device 3 (decentralized intelligence).

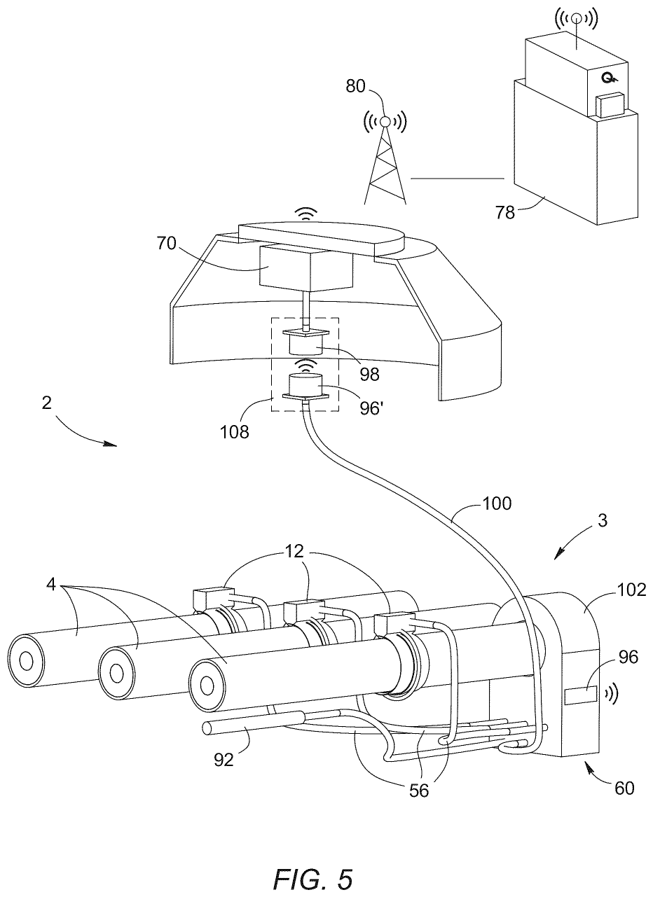

With reference to FIG. 7, in the case of MV cables 4 with semiconductor sheath 32 and concentric neutral 110 (illustrated in FIG. 6) in an underground distribution network, there is an intrinsic capacitor formed by the central conductor 106 of the cable 4 and the semiconductor sheath 32 separated by an insulator 108. The equation for finding the capacitance of a coaxial-type conductor (with outer sheath) is as follows:

$${C}_{Cable ( Farads )} = {C}_{insulator ( Farads )} = \frac{2 π ε}{ln \frac{R}{r}} * L$$

where ε is the dielectric permittivity of insulator 108, calculated as ε=ε₀εᵣ, ε₀ is the vacuum permittivity (8.85418782×10⁻¹² F/m), εᵣ is the relative dielectric permittivity of insulator 108, r is the radius of conductor 106, R is the inner radius of outer sheath 32, and L is the conductor length in meters.

To complete the model between a measuring point on the semiconductor 32 and the main conductor 106, it is important to note that a conduction occurs between the concentric neutral 110 (shown in FIG. 6) and the semiconductor layer 32. The value of the conduction (or impedance) varies according to the position of the measuring point (distance from the concentric neutral 110 on the stripped length 32 of the underground cable 4.

Several other factors can also affect the value of this conduction, including:
the length of the stripped section of concentric neutral 110 (illustrated in FIG. 6);
the length of cable 4;
the presence of water and its salinity on cable 4;
the quality of the concentric neutral 110 (oxidation, mechanical pressure, breakage, etc.);
the type of nearby junction 112 (shown in FIG. 6) and the quality of its installation.

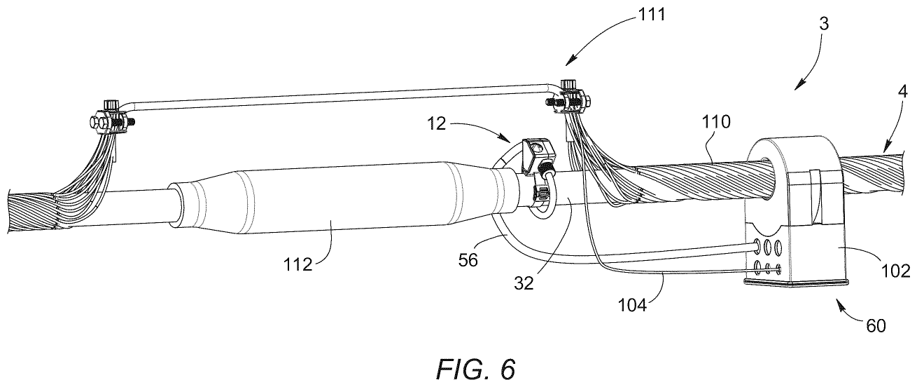

With reference to FIG. 8, which shows a simplified model of an underground MV cable, to stabilize the impedance between the concentric neutral 110 (shown in FIG. 6) and the semiconductor 32, the VIT 12 probe (shown e.g. at in FIG. 6) forces an equipotential electrical reference (e.g. ground) around a sensing surface of semiconductor 32 using conductive shield 28A, 28B (shown e.g. in FIGS. 3A and 3B). Then, to capture the residual voltage on the semiconductor 32 safely (without direct contact), capacitive coupling using the insulated electrode 18 (by a polyimide layer 22) inside the flexible printed circuit board 16 (“pcb”) is used. Another conductive layer 20 (shown e.g. in FIGS. 3A and 3B) behind electrode 18, separated by a thin Kapton insulator 24, is grounded 104 (shown in FIG. 6) to create a reference and block coupling with external electric fields. The conductive shield 28 also has the effect of desensitizing the voltage measurement between the sensing electrode 18 and the reference electrode 20 in the presence of a semiconductor 32 having variable contact with the concentric neutral 110, which may itself be located at a variable distance from the voltage sensor 14 (illustrated e.g. in FIG. 4A or in FIG. 4B).

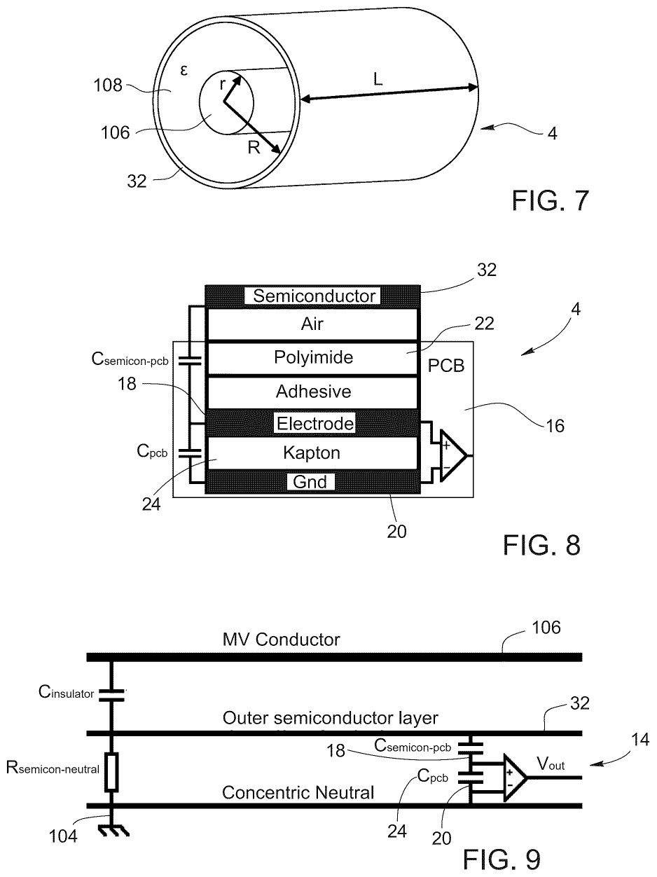

With reference to FIG. 9 representing a simplified model of the flexible printed circuit board 16 for capacitive coupling, the clamping assembly 34 (illustrated in FIG. 3A) is used to apply a force to the flexible printed circuit board 16 and bring it into contact with the semiconductor 32. The distance between the semiconductor 32 and the flexible printed circuit board 16 reduces the coupling between them, and thus the amplitude of the available signal. The output voltage of voltage sensor 14 can then be calculated as follows:

$${Z}_{semicon} = \frac{1}{\frac{1}{{Xc}_{semicon - pcb} + {Xc}_{pcb}} + \frac{1}{{R}_{semicon - neutral}}}$$

$${V}_{semicon} = \frac{{V}_{avg voltage} * {Z}_{semicon}}{{Z}_{semicon} + {Xc}_{i n s u l a t o γ}}$$

$${V}_{output} = \frac{{V}_{semicon} * {Xc}_{pcb}}{{Xc}_{semicon - pcb} + {Xc}_{pcb}}$$

The phase of the output signal from the VIT probe 12 (shown e.g. in FIG. 1) will be the phase of the signal on the main conductor 106, but with a phase lead of almost 90° due to:

$$( {Xc}_{insulator} >> {R}_{semicon} ) and ( ( {Xc}_{semicon - pcb} + {Xc}_{pcb} ) >> {R}_{semicon} )$$

If required by the application, the phase advance can be corrected digitally in the remote server 78 (shown e.g. in FIG. 1), in the controller 68 of the measuring device 3 (shown in FIG. 1) or analogue at the probe 12 by adding a phase retarder (integrator) circuit (not shown).

In the absence of an outer semiconductor layer 32 on the cable, no phase advance will be present, as R_{semicon-neutral} will be infinite and c_{semicon-pch} will be short-circuited (shown in FIG. 9). In this case, a phase-neutral filter would be advantageous.

The amplitude of the output signal will be influenced by the type of cable where the measuring device 3 will be installed (Xcᵢₙₛᵤₗₐₜₒᵣ variable), by the coupling of electrode 18 (shown in FIGS. 3A and 3B) of the flexible printed circuit board 16 with semiconductor 32 (Xc_{semicon-pcb} variable) and by the resistance between semiconductor 32 and ground 104 (R_{semicon-neutral} variable even if strongly controlled by ground 104 forced onto semiconductor 32 by shield 28 (shown in FIGS. 3A and 3B) of the probe).

If required, the exact amplitude of the medium-voltage signal can be obtained with the addition of a circuit that injects signals of different frequencies onto electrode 18 of the VIT probe 12 so as to measure the impedances of the complete system.

Although embodiments of the invention have been illustrated in the accompanying drawings and described above, it will be apparent to those skilled in the art that modifications can be made to these embodiments without departing from the invention.

According to some aspects, embodiments of the present technology comprise the following elements:

### [Element 1]

A probe for a power line phase cable, the probe comprising:
an electrical voltage sensor having:
   a flexible printed circuit board configured to extend over a stripped circumferential surface of a concentric neutral of the phase cable and including a capacitive divider for measuring a conductor voltage; and
   an electrically conductive shield extending over respective lateral sides of the flexible printed circuit board defining first contact surfaces with the circumferential surface of the phase cable, the shield including a connection to a local ground and to the capacitive divider to define an equipotential electrical reference of the shield and the capacitive divider;
a clamping assembly configured to press the shield and the flexible printed circuit board against the circumferential surface of the phase cable; and
a housing containing circuitry connected to the voltage sensor, the circuitry having an output for transmitting a signal indicative of the voltage measured by the voltage sensor.

### [Element 2]

The probe of element 1, wherein the phase cable is formed of a central conductor covered with an electrical insulator and a semiconductor, and the flexible printed circuit board is configured to extend over a surface of the semiconductor.

### [Element 3]

The probe of element 1 or 2, wherein the shield comprises first flexible shield elements defining first contact surfaces with the circumferential surface of the phase cable, the first shield elements being formed by at least one wire having a diameter similar to a thickness of the flexible printed circuit board, and segments extending along lateral sides of the flexible printed circuit board.

### [Element 4]

The probe of any one of elements 1 to 3, wherein the shield comprises second shield elements extending over ends of the flexible printed circuit board and defining second contact surfaces with the circumferential surface of the phase cable, the first and second shield elements being interconnected without forming a closed loop around the flexible printed circuit board.

### [Element 5]

The probe of any one of elements 1 to 4, wherein the flexible printed circuit board comprises first and second printed circuit layers sandwiched between electrically insulating layers defining the capacitive divider, the first printed circuit layer being closer to the phase cable than the second printed circuit layer, the signal indicative of the voltage measured by the voltage sensor corresponding to a voltage between the first and second printed circuit layers.

### [Element 6]

The probe of element 5, wherein the shield comprises a connection to the local ground and to the second printed circuit layer.

### [Element 7]

The probe of any one of elements 1 to 6, further comprising a current sensor having a sensing element for sensing current flowing in the phase cable to produce a signal indicative of the current, the circuitry being connected to the current sensor and having an output for transmitting the signal indicative of the current.

### [Element 8]

The probe of element 7, wherein the current sensor comprises a Rogowski winding assembly installable around the phase cable to produce the signal indicative of the current.

### [Element 9]

The probe of element 8 or 9, wherein the voltage and current sensors have a common concentric axis, the current sensor extending on an outer side of the voltage sensor relative to the phase cable.

### [Element 10]

The probe of any one of elements 1 to 9, wherein the clamping assembly comprises an adjustable clamp for pressing against the printed circuit board in the radial direction towards the phase cable.

### [Element 11]

The probe of element 10, wherein the clamping assembly comprises a tongue projecting from the housing and extending around the phase cable; and the adjustable clamp is configured to press on the tongue in the radial direction towards the phase cable.

### [Element 12]

The probe of element 10, wherein the adjustable clamp is integral with the shield.

### [Element 13]

The probe of any one of elements 1 to 12, wherein:
the housing has a bottom face that is complementary with the circumferential surface of the phase cable for positioning the housing on or near the phase cable; and
the flexible printed circuit board projects out of the housing in contiguity with the lower face of the housing in a direction of the circumferential surface.

### [Element 14]

The probe of any one of elements 1 to 12, comprising a temperature sensor for measuring a temperature in proximity to the phase cable and producing a signal indicative of the temperature, the temperature sensor being connected to the circuitry, the circuitry having an output for transmitting the signal indicative of the temperature.

### [Element 15]

The probe of element 14, wherein:
the housing has a bottom face compatible with the circumferential surface of the phase cable for positioning the housing on or near the phase cable; and
the temperature sensor is housed in the case close to or in contact with the lower face of the case.

### [Element 16]

The probe of any one of elements 1 to 15, wherein the housing defines a sealed chamber filled with a sealant, the probe further comprising a sealed multipair cross-over cable connected to the circuitry and exiting the housing, the multipair cable having a shield connected to the local ground.

### [Element 17]

The probe of any one of elements 1 to 16, wherein the circuitry comprises a conditioning circuit integrated on the flexible printed circuit board to produce the signal indicative of the voltage.

### [Element 18]

A device for measuring operating and environmental parameters of a power line, the measuring device comprising:
for each phase cable of the power line, a probe installable around the phase cable, the probe being configured according to any one of elements 1 to 17 and comprising circuitry for transmitting the signal indicative of the measured voltage; and
an acquisition unit having:
   a power supply circuit connectable to a power supply source, the circuitry of each probe being powered by the power supply circuit;
   an acquisition circuit powered by the power supply circuit, the acquisition circuit having inputs for receiving analog signals and digital signals including the signals transmitted by the circuitry of each probe, an analog-to-digital converter for converting the analog signals into digital signals, and an output for transmitting data representing the digital signals; and
   a controller powered by the power supply circuit and connected to the acquisition circuit, the controller having a programmable operating mode defining data processing including data transmitted by the acquisition circuit and a controller response, and a communication interface for transmitting the data processed by the controller and receiving controller operating mode programming data.

### [Element 19]

A system for monitoring phase cables of a power line, the monitoring system comprising:
for each phase cable of the power line, a probe installable around the phase cable, the probe being configured according to any one of elements 1 to 17 and comprising a circuit for transmitting the signal indicative of the measured voltage;
an acquisition unit connectable to a power supply, the acquisition unit having inputs for receiving analog signals and digital signals including the signals transmitted by the circuitry of each probe, circuitry for processing the signals received at the inputs including a circuit having a programmable mode of operation defining a processing of the signals received at the inputs and a response of the acquisition unit, and a communication interface for transmitting data processed by the acquisition unit and receiving data for programming the mode of operation of the circuitry having a programmable mode of operation; and
a communication gateway connected to the communication interface of the acquisition unit, the communication gateway having a circuit for transmitting the data to a remote server via a telecommunication network and receiving the programming data from the remote server via the telecommunication network.

### [Element 20]

A device for measuring operating and environmental parameters of a power line, the measuring device comprising:
for each phase cable of the power line, a probe that can be installed around the phase cable, the probe comprising:
   at least one of the following sensors: a voltage sensor for sensing the electrical voltage of a conductor of the phase cable, a current sensor for sensing current flowing in the conductor of the phase cable, and a temperature sensor in the vicinity of the phase cable; and
   circuitry for transmitting signals indicative of measurements by the sensors; and
an acquisition unit having:
   a power supply circuit connectable to a power supply, the circuitry of each sensor being powered by the power supply circuit;
   an acquisition circuit powered by the supply circuit, the acquisition circuit having inputs for receiving analog signals and digital signals including the signals transmitted by the circuitry of each probe, an analog-to-digital converter for converting the analog signals into digital signals, and an output for transmitting data representing the digital signals; and
   a controller powered by the power supply circuit and connected to the acquisition circuit, the controller having a programmable mode of operation defining data processing including data transmitted by the acquisition circuit and a controller response, and a communication interface for transmitting the data processed by the controller and receiving data for programming the mode of operation of the controller.

### [Element 21]

The measuring device of element 20, wherein the power supply source comprises a current transformer coupled to one of the phase cables to sense a magnetic field generated by the phase cable and generate electrical power supplied to the power supply circuit.

### [Element 22]

The measuring device of element 21, wherein the power supply circuit comprises:
an input current rectifier, connected to the current transformer, for converting the electrical energy received from the current transformer in the form of an alternating current into a regulated low DC voltage;
an accumulator for storing and releasing electrical energy; and
a maximum output power point tracking regulator, connected to the current rectifier and the accumulator, to recharge the accumulator with excess electrical energy and draw electrical energy from the accumulator to maintain a minimum output power level.

### [Element 23]

The measuring device of element 22, wherein the accumulator comprises a hybrid supercapacitor type accumulator.

### [Element 24]

The measuring device of any one of elements 20 to 23, wherein the acquisition unit comprises input anti-aliasing filters and a circuit for conditioning analog signals prior to digitization by the analog-to-digital converter.

### [Element 25]

The measuring device of any one of elements 20 to 24, wherein the controller of the acquisition unit has an interface connectable to measuring instruments external to the measuring device.

### [Element 26]

The measuring device of any one of elements 20 to 25, wherein the acquisition unit comprises an internal temperature sensor for producing a signal indicative of a temperature in an environment of the acquisition unit.

### [Element 27]

A system for monitoring phase cables of a power line, the monitoring system comprising:
for each phase cable of the power line, a probe installable around the phase cable, the probe comprising:
   at least one of the following sensors: a voltage sensor for sensing the electrical voltage of a conductor of the phase cable, a current sensor for sensing the current flowing in the conductor of the phase cable, and a temperature sensor for sensing the temperature in the vicinity of the phase cable; and
   circuitry for transmitting signals indicative of measurements by the sensors;
an acquisition unit connectable to a power supply, the acquisition unit having inputs for receiving analog signals and digital signals including signals transmitted by the circuitry of each probe, circuitry for processing signals received at the inputs including a circuit having a programmable mode of operation defining processing of signals received at the inputs and a response from the acquisition unit, and a communication interface for transmitting data processed by the acquisition unit and receiving data for programming the mode of operation of the circuitry having a programmable mode of operation; and
a communication gateway connected to the communication interface of the acquisition unit, the communication gateway having a circuit for transmitting the data to a remote server via a telecommunication network and receiving the programming data from the remote server via the telecommunication network.

### [Element 28]

The monitoring system of element 27, wherein the acquisition unit and the gateway have an antenna or cable connection.

What is claimed is:

1. A probe for a power line phase cable, the probe comprising:
an electrical voltage sensor having:
a flexible printed circuit board configured to extend over a stripped circumferential surface of a concentric neutral of the phase cable and including a capacitive divider for measuring a conductor voltage; and
an electrically conductive shield extending over respective lateral sides of the flexible printed circuit board defining first contact surfaces with the circumferential surface of the phase cable, the shield including a connection to a local ground and to the capacitive divider to define an equipotential electrical reference of the shield and the capacitive divider;
a clamping assembly configured to press the shield and the flexible printed circuit board against the circumferential surface of the phase cable; and
a housing containing circuitry connected to the voltage sensor, the circuitry having an output for transmitting a signal indicative of the voltage measured by the voltage sensor.

2. The probe of claim 1, wherein the phase cable is formed of a central conductor covered with an electrical insulator and a semiconductor, and the flexible printed circuit board is configured to extend over a surface of the semiconductor.

3. The probe of claim 1, wherein the shield comprises first flexible shield elements defining first contact surfaces with the circumferential surface of the phase cable, the first shield elements being formed by at least one wire having a diameter similar to a thickness of the flexible printed circuit board, and segments extending along lateral sides of the flexible printed circuit board.

4. The probe of claim 1, wherein the shield comprises second shield elements extending over ends of the flexible printed circuit board and defining second contact surfaces with the circumferential surface of the phase cable, the first and second shield elements being interconnected without forming a closed loop around the flexible printed circuit board.

5. The probe of claim 1, wherein the flexible printed circuit board comprises first and second printed circuit layers sandwiched between electrically insulating layers defining the capacitive divider, the first printed circuit layer being closer to the phase cable than the second printed circuit layer, the signal indicative of the voltage measured by the voltage sensor corresponding to a voltage between the first and second printed circuit layers.

6. (canceled)

7. The probe of claim 1, further comprising a current sensor having a sensing element for sensing current flowing in the phase cable to produce a signal indicative of the current, the circuitry being connected to the current sensor and having an output for transmitting the signal indicative of the current.

8. (canceled)

9. The probe of claim 7, wherein the voltage and current sensors have a common concentric axis, the current sensor extending on an outer side of the voltage sensor relative to the phase cable.

10. The probe of claim 1, wherein the clamping assembly comprises an adjustable clamp for pressing against the printed circuit board in the radial direction towards the phase cable.

11. (canceled)

12. (canceled)

13. The probe of claim 1, wherein:
the housing has a bottom face that is complementary with the circumferential surface of the phase cable for positioning the housing on or near the phase cable; and
the flexible printed circuit board projects out of the housing in contiguity with the lower face of the housing in a direction of the circumferential surface.

14. The probe of claim 1, comprising a temperature sensor for measuring a temperature in proximity to the phase cable and producing a signal indicative of the temperature, the temperature sensor being connected to the circuitry, the circuitry having an output for transmitting the signal indicative of the temperature.

15. The probe of claim 14, wherein:
the housing has a bottom face compatible with the circumferential surface of the phase cable for positioning the housing on or near the phase cable; and
the temperature sensor is housed in the case close to or in contact with the lower face of the case.

16. The probe of claim 1, wherein the housing defines a sealed chamber filled with a sealant, the probe further comprising a sealed multipair cross-over cable connected to the circuitry and exiting the housing, the multipair cable having a shield connected to the local ground.

17. The probe of claim 1, wherein the circuitry comprises a conditioning circuit integrated on the flexible printed circuit board to produce the signal indicative of the voltage.

18. A device for measuring operating and environmental parameters of a power line, the measuring device comprising:
for each phase cable of the power line, a probe installable around the phase cable, the probe being configured according to claim 1 and comprising circuitry for transmitting the signal indicative of the measured voltage; and
an acquisition unit having:
a power supply circuit connectable to a power supply source, the circuitry of each probe being powered by the power supply circuit;
an acquisition circuit powered by the power supply circuit, the acquisition circuit having inputs for receiving analog signals and digital signals including the signals transmitted by the circuitry of each probe, an analog-to-digital converter for converting the analog signals into digital signals, and an output for transmitting data representing the digital signals; and
a controller powered by the power supply circuit and connected to the acquisition circuit, the controller having a programmable operating mode defining data processing including data transmitted by the acquisition circuit and a controller response, and a communication interface for transmitting the data processed by the controller and receiving controller operating mode programming data.

19. A system for monitoring phase cables of a power line, the monitoring system comprising:
for each phase cable of the power line, a probe installable around the phase cable, the probe being configured according to claim 1 and comprising a circuit for transmitting the signal indicative of the measured voltage;
an acquisition unit connectable to a power supply, the acquisition unit having inputs for receiving analog signals and digital signals including the signals transmitted by the circuitry of each probe, circuitry for processing the signals received at the inputs including a circuit having a programmable mode of operation defining a processing of the signals received at the inputs and a response of the acquisition unit, and a communication interface for transmitting data processed by the acquisition unit and receiving data for programming the mode of operation of the circuitry having a programmable mode of operation; and
a communication gateway connected to the communication interface of the acquisition unit, the communication gateway having a circuit for transmitting the data to a remote server via a telecommunication network and receiving the programming data from the remote server via the telecommunication network.

20. A device for measuring operating and environmental parameters of a power line, the measuring device comprising:
for each phase cable of the power line, a probe that can be installed around the phase cable, the probe comprising:
at least one of the following sensors: a voltage sensor for sensing the electrical voltage of a conductor of the phase cable, a current sensor for sensing current flowing in the conductor of the phase cable, and a temperature sensor in the vicinity of the phase cable; and
circuitry for transmitting signals indicative of measurements by the sensors; and
an acquisition unit having:
a power supply circuit connectable to a power supply, the circuitry of each sensor being powered by the power supply circuit;
an acquisition circuit powered by the supply circuit, the acquisition circuit having inputs for receiving analog signals and digital signals including the signals transmitted by the circuitry of each probe, an analog-to-digital converter for converting the analog signals into digital signals, and an output for transmitting data representing the digital signals; and
a controller powered by the power supply circuit and connected to the acquisition circuit, the controller having a programmable mode of operation defining data processing including data transmitted by the acquisition circuit and a controller response, and a communication interface for transmitting the data processed by the controller and receiving data for programming the mode of operation of the controller.

21. The measuring device of claim 20, wherein the power supply source comprises a current transformer coupled to one of the phase cables to sense a magnetic field generated by the phase cable and generate electrical power supplied to the power supply circuit.

22. The measuring device of claim 21, wherein the power supply circuit comprises:
an input current rectifier, connected to the current transformer, for converting the electrical energy received from the current transformer in the form of an alternating current into a regulated low DC voltage;
an accumulator for storing and releasing electrical energy; and
a maximum output power point tracking regulator, connected to the current rectifier and the accumulator, to recharge the accumulator with excess electrical energy and draw electrical energy from the accumulator to maintain a minimum output power level.

23. (canceled)

24. (canceled)

25. (canceled)

26. The measuring device of claim 20, wherein the acquisition unit comprises an internal temperature sensor for producing a signal indicative of a temperature in an environment of the acquisition unit.

27. A system for monitoring phase cables of a power line, the monitoring system comprising:
for each phase cable of the power line, a probe installable around the phase cable, the probe comprising:
at least one of the following sensors: a voltage sensor for sensing the electrical voltage of a conductor of the phase cable, a current sensor for sensing the current flowing in the conductor of the phase cable, and a temperature sensor for sensing the temperature in the vicinity of the phase cable; and
circuitry for transmitting signals indicative of measurements by the sensors;
an acquisition unit connectable to a power supply, the acquisition unit having inputs for receiving analog signals and digital signals including signals transmitted by the circuitry of each probe, circuitry for processing signals received at the inputs including a circuit having a programmable mode of operation defining processing of signals received at the inputs and a response from the acquisition unit, and a communication interface for transmitting data processed by the acquisition unit and receiving data for programming the mode of operation of the circuitry having a programmable mode of operation; and
a communication gateway connected to the communication interface of the acquisition unit, the communication gateway having a circuit for transmitting the data to a remote server via a telecommunication network and receiving the programming data from the remote server via the telecommunication network.

28. (canceled)
